(19) United States
(12) Patent Application Publication
(10) Pub. No.: US 2025/0174965 A1
(43) Pub. Date: May 29, 2025

(54) VERTICAL-CAVITY SURFACE-EMITTING LASER THAT PROVIDES POLARIZATION MODE CONTROL

(71) Applicant: Lumentum Operations LLC, San Jose, CA (US)

(72) Inventors: Chien-Yao LU, San Jose, CA (US); Mike TAN, Menlo Park, CA (US); Albert YUEN, Palo Alto, CA (US)

(21) Appl. No.: 18/418,704

(22) Filed: Jan. 22, 2024

Related U.S. Application Data
(60) Provisional application No. 63/602,926, filed on Nov. 27, 2023.

(51) Int. Cl. H01S 5/183; H01S 5/065; H01S 5/42

(52) U.S. Cl. CPC H01S 5/18302; H01S 5/0653; H01S 5/18355; H01S 5/18394; H01S 5/423

(57) ABSTRACT

In some implementations, a vertical-cavity surface-emitting laser (VCSEL) includes a confinement layer and a polarization mode filter. The confinement layer defines a confinement aperture. The confinement aperture is asymmetrical with respect to at least one axis of the confinement aperture. The polarization mode filter includes a grating. The confinement aperture and the polarization mode filter are configured to control a quantity of optical modes supported by the VCSEL and to lock a polarization of each optical mode supported by the VCSEL.

### CROSS-REFERENCE TO RELATED APPLICATION

This patent application claims priority to U.S. Patent Application No. 63/602,926, filed on Nov. 27, 2023, and entitled “VERTICAL-CAVITY SURFACE-EMITTING LASER WITH INTEGRATED GRATING FOR POLARIZATION MODE CONTROL.” The disclosure of the prior application is considered part of and is incorporated by reference into this patent application.

### TECHNICAL FIELD

The present disclosure relates generally to a vertical-cavity surface-emitting laser (VCSEL) and to VCSEL that provides polarization mode control.

### BACKGROUND

An emitter can include a vertical-emitting device, such as a VCSEL. A VCSEL is a laser in which a laser beam is emitted in a direction perpendicular to a surface of the VCSEL (e.g., vertically from a surface of the VCSEL). Multiple emitters may be arranged in an emitter array with a common substrate.

### SUMMARY

In some implementations, a VCSEL includes a confinement layer; and a polarization mode filter, wherein: the confinement layer defines a confinement aperture, the confinement aperture is asymmetrical with respect to at least one axis of the confinement aperture, and the polarization mode filter includes a grating, and the confinement aperture and the polarization mode filter are configured to control a quantity of optical modes supported by the VCSEL and to lock a polarization of each optical mode supported by the VCSEL.

In some implementations, an optical assembly includes one or more VCSELs, wherein each VCSEL comprises: a confinement layer; and a polarization mode filter, wherein: the confinement layer defines a confinement aperture, and the confinement aperture and the polarization mode filter are configured to control a quantity of optical modes supported by the VCSEL and to lock a polarization of each optical mode supported by the VCSEL.

In some implementations, a wafer includes a plurality of VCSELs, wherein each VCSEL comprises: a confinement layer that defines a confinement aperture; and a polarization mode filter, wherein: the confinement aperture and the polarization mode filter are configured to control a quantity of optical modes supported by the VCSEL and to lock a polarization of each optical mode supported by the VCSEL.

### BRIEF DESCRIPTION OF THE DRAWINGS

FIG. 1 is a diagram associated with an example VCSEL.

FIGS. 2A-2B are diagrams depicting top-views of different configurations of the example VCSEL.

FIGS. 3A-3B are example diagrams related to a polarization mode filter of the example VCSEL.

FIG. 4 is diagram associated with an example optical device.

FIG. 5 is diagram associated with an example wafer.

### DETAILED DESCRIPTION

The following detailed description of example implementations refers to the accompanying drawings. The same reference numbers in different drawings may identify the same or similar elements.

A VCSEL includes a laser cavity that can comprise a cylindrical waveguide, defined by an aperture, to confine propagating optical energy. Top and bottom mirrors are often deposited or grown on two sides of the cylindrical waveguide (e.g., a top and a bottom of the cylindrical waveguide) to form the laser cavity. The cylindrical waveguide, notably, can support numerous optical modes (also referred to as resonant optical modes) with different propagation speeds, spatial distributions, and polarizations. Controlling, or reducing, a quantity of optical modes within the VCSEL is based, at least in part, on a geometry of the cylindrical waveguide (e.g., an aperture size, shape, and/or other dimension), as well as reflective properties of the top and bottom mirrors.

In many cases, an aperture of a VCSEL (e.g., that includes a cylindrical waveguide) defines a symmetry of propagation of the optical modes (e.g., within the cylindrical waveguide). Optical energy distribution then spatially follows the symmetry. In some cases, optical modes with a same symmetry have an identical (or near-identical) propagation speed (i.e., degeneracy), and different linear combinations of those optical modes can have different polarizations that coexist in a laser cavity of the VCSEL (e.g., within the cylindrical waveguide). When the cylindrical waveguide of the VCSEL supports degenerate optical modes and the degenerate optical modes follow the symmetry of propagation, optical modes with different polarizations can occur inside the laser cavity. A linear combination of the optical modes (e.g., a linear combination ratio) often varies over driving currents, and thereby a polarization, which is determined by the linear combination ratio, changes (e.g., randomly, or unpredictably) over an operating current range. Polarization cannot be locked by adjusting only aperture geometry.

In some cases, an excess beating noise can occur when the optical modes interact with each other within the VCSEL (e.g., within the laser cavity of the VCSEL). Other effects, such as spatial hole burning and sudden divergence angle, that occur due to changes in an operating current of the VCSEL, can also cause issues when the optical modes do not have a locked polarization (e.g., an unchanging polarization). Thus, minimizing these types of interactions and effects is important for improving optical signal quality of a laser beam emitted by the VCSEL, such as to facilitate optical communication and/or optical sensing.

Some implementations described herein include a VCSEL that has a confinement layer and a polarization mode filter. The confinement layer defines a confinement aperture, and the confinement aperture and the polarization mode filter are configured to control a quantity of optical modes supported by the VCSEL and to lock a polarization of each optical mode supported by the VCSEL.

For example, the confinement aperture may be asymmetrical with respect to at least one axis of the confinement aperture, which can reduce the quantity of optical modes supported by the VCSEL (e.g., by enabling enhancement of one optical mode and reduction and/or elimination of one or more other optical modes). Additionally, the polarization mode filter may suppress one of two orthogonal polarization orientations of light such that every optical mode supported by the VCSEL has a single polarization orientation. For example, the polarization mode filter may include a grating, which allows light associated with one polarization orientation (e.g., that is aligned with a grating axis of the grating) to be reflected and light associated with an orthogonal polarization orientation to be blocked. This causes each optical mode supported by the VCSEL to have a locked polarization (e.g., along the grating axis of the grating of the polarization mode filter).

In this way, some implementations described herein include a VCSEL that provides polarization mode control. By controlling a quantity of optical modes supported by the VCSEL and by locking a polarization of each optical mode supported by the VCSEL, a likelihood of excess beating noise that can occur based on interactions of optical modes within the VCSEL is reduced and/or eliminated (e.g., because of a reduced number of optical modes, which each have a locked polarization). Further, other effects, such as spatial hole burning and sudden divergence angle, are less likely to occur because the optical modes have locked polarizations. Thus, the VCSEL emits a laser beam with an improved optical signal quality (e.g., as compared to a laser beam emitted by a VCSEL that does not have the confinement layer and the polarization mode filter, as described herein), which can facilitate improvement in optical communication applications, optical sensing applications, or any other optical application where an improved optical signal quality is needed.

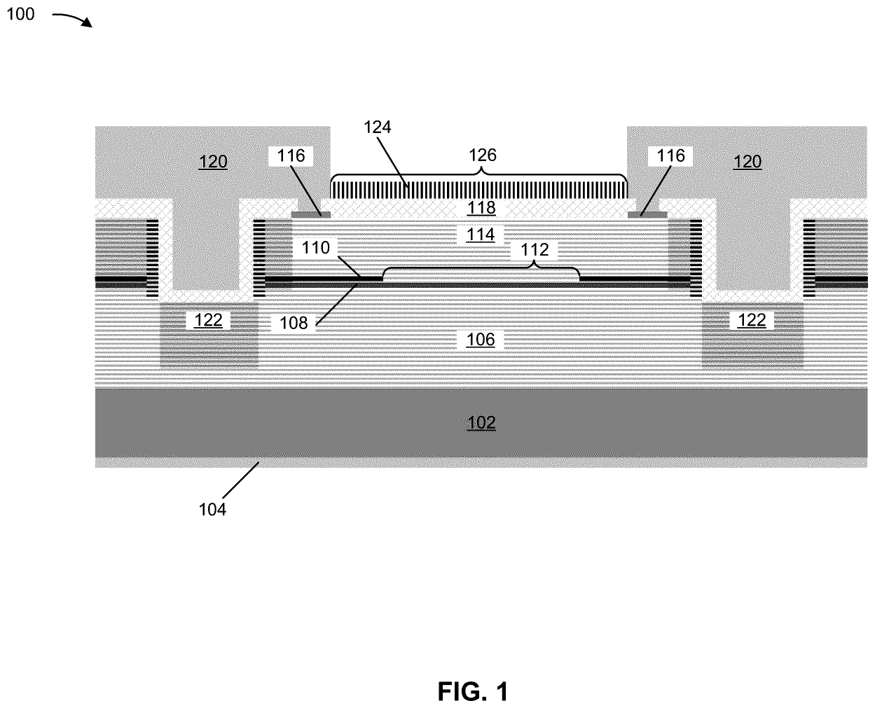

FIG. 1 is a diagram associated with an example VCSEL 100. In some implementations, the VCSEL 100 may be included in an array of emitters (e.g., an array of VCSELs 100). In some implementations, as illustrated in FIG. 1, the VCSEL 100 is a top-emitting emitter. Alternatively, the VCSEL 100 may in some implementations be a bottom-emitting emitter (e.g., with a similar structure to that shown in FIG. 1, with modifications to enable bottom-emitting). As shown in FIG. 1, the VCSEL 100 may include a substrate 102, a bottom metal 104, a bottom mirror structure 106, a cavity including one or more an active regions (herein referred to as cavity region 108), a confinement layer 110 that forms a confinement aperture 112, a top mirror structure 114, a top contact layer 116, a dielectric layer 118, a top metal 120, one or more isolation implants 122, and/or a polarization mode filter 124. As shown, one or more layers of the VCSEL 100 (e.g., the top contact layer 116, the dielectric layer 118, the top metal 120, the polarization mode filter 124, or the like) may form an output aperture 126.

Substrate 102 includes a supporting material upon which, or within which, one or more layers or features of the VCSEL 100 are grown or fabricated. In some implementations, the substrate 102 includes an n-type material. In some implementations, the substrate 102 includes a semi-insulating type of material. In some implementations, the semi-insulating type of material may be used when the VCSEL 100 includes one or more bottom-emitting emitters in order to reduce optical absorption from the substrate 102. In such an implementation, the VCSEL 100 may include a contact buffer in or near the bottom mirror structure 106. In some implementations, the substrate 102 may be formed from a semiconductor material, such as gallium arsenide (GaAs), aluminum gallium arsenide (AlGaAs), indium phosphide (InP), or another type of semiconductor material. In some implementations, a bottom contact (e.g., a bottom n-contact) of the VCSEL 100 can be made from a backside of the substrate 102. In some implementations, the bottom contact of the VCSEL 100 can be made from a front side of the VCSEL 100. In some implementations, the front side contact can be achieved by, for example, etching a mesa step or trench to the substrate 102, or inserting a contact buffer in or near the bottom mirror structure 106.

Bottom metal 104 includes a metal layer on a bottom surface of the substrate 102 (e.g., at a backside of the VCSEL 100). In some implementations, the bottom metal 104 is formed from an n-type material. In some implementations, the bottom metal 104 is a layer that makes electrical contact with the substrate 102. In some implementations, the bottom metal 104 serves as an anode for the VCSEL 100. In some implementations, the bottom metal 104 may include an annealed metallization layer, such as a gold-germanium-nickel (AuGeNi) layer, a palladium-germanium-gold (PdGeAu) layer, among other examples.

Bottom mirror structure 106 is a bottom reflector of an optical resonator of the VCSEL 100. For example, the bottom mirror structure 106 may include a distributed Bragg reflector (DBR), a dielectric mirror, or another type of mirror structure. In some implementations, the bottom mirror structure 106 is formed from an n-type material. In some implementations, the bottom mirror structure 106 is on a top surface of the substrate 102. In some implementations, the bottom mirror structure 106 may have a thickness in a range from approximately 3.5 micrometers (μm) to approximately 9 μm (e.g., greater than or equal to 3.5 μm and less than or equal to 9 μm), such as 5 μm. In some implementations, the bottom mirror structure 106 includes a set of layers (e.g., aluminum gallium arsenide (AlGaAs) layers) grown using a metal-organic chemical vapor deposition (MOCVD) technique, a molecular beam epitaxy (MBE) technique, or another technique.

Cavity region 108 includes one or more layers where electrons and holes recombine to emit light and define the emission wavelength range of the VCSEL 100. For example, the cavity region 108 may include one or more active regions in the form of one or more quantum wells (QWs). In some implementations, the cavity region 108 may include one or more cavity spacer layers (e.g., to enable epitaxial growth to have sufficient room for ramping compositions or temperature). In some implementations, the one or more cavity spacer layers may reduce strain between active regions of the cavity region 108 and/or may mitigate thermal issues of laser operation of the VCSEL 100. In some implementations, the one or more cavity spacer layers may include an oxidation layer. An optical thickness of the cavity region 108 (including the one or more active regions and any cavity spacer layers), the top mirror structure 114, and the bottom mirror structure 106 defines the resonant cavity wavelength of the VCSEL 100, which may be designed within an emission wavelength range of the cavity region 108 to enable lasing. In some implementations, the cavity region 108 may be formed on the bottom mirror structure 106. In some implementations, the cavity region 108 may have a thickness in a range from approximately 0.006 μm to approximately 0.5 μm, such as 0.15 μm or 0.30 μm. In some implementations, the cavity region 108 includes a set of layers grown using an MOCVD technique, an MBE technique, or another technique.

Confinement layer 110 is a layer that provides optical and/or electrical confinement for the VCSEL 100. In some implementations, the confinement layer 110 enhances carrier and optical mode confinement of the VCSEL 100 and, therefore, can improve performance of the VCSEL 100. In some implementations, the confinement layer 110 is on, under, or in the cavity region 108. In some implementations, there may be one or more spacer layers or mirror layers (e.g., DBRs) between the confinement layer 110 and the cavity region 108. In some implementations, the confinement layer 110 is on a side of the cavity region 108 nearer to the bottom mirror structure 106 (i.e., on a substrate side of the cavity region 108) (e.g., the confinement layer 110 may be below the cavity region 108). In some implementations, the confinement layer 110 is on a side of the cavity region 108 nearer to the top mirror structure 114 (i.e., on a non-substrate side of the cavity region 108) (e.g., the confinement layer 110 may be above the cavity region 108).

In some implementations, the confinement layer 110 is an oxide layer formed as a result of oxidation of one or more epitaxial layers of the VCSEL 100. For example, the confinement layer 110 may be an aluminum oxide (Al₂O₃) layer formed as a result of oxidation of an epitaxial layer (e.g., an AlGaAs layer, an AlAs layer, or the like). In some implementations, the confinement layer 110 may have a thickness in a range from approximately 0.007 μm to approximately 0.04 μm, such as 0.02 μm. In some implementations, oxidation trenches (shown as filled in FIG. 1) etched around the VCSEL 100 may allow steam to access the epitaxial layer(s) from which the confinement layer 110 is formed. In some implementations, the oxidation trenches may not fully enclose the confinement layer 110. For example, the oxidation trenches may follow the general shape of the confinement region, but there may be gaps between adjacent oxidation trenches. In some implementations, the confinement layer 110 may follow the general geometric shape, but may have variations associated with shapes or locations of the oxidation trenches and/or variations associated with an oxidation rate. In some implementations, in addition to the confinement layer 110, the VCSEL 100 may include one or more other types of structures or layers that provide current confinement, such as an implant passivation structure, a mesa isolation structure, a moat trench isolation structure, a buried tunnel junction, or the like. Additionally, or alternatively, such other types of structures or layers for providing current confinement may be included in or integrated with the confinement layer 110.

In some implementations, the confinement layer 110 defines the confinement aperture 112. Thus, in some implementations, the confinement aperture 112 is an optically active aperture defined by the confinement layer 110. In some implementations, a size (e.g., a width in a given direction) of the confinement aperture 112 is in a range from approximately 1 μm to approximately 300 μm, such as 5 μm or 8 μm. In some implementations, the confinement aperture 112 may be formed by oxidation (e.g., when the confinement layer 110 is an oxidized layer). Additionally, or alternatively, the confinement aperture 112 may be formed by other means, such as by implantation, diffusion, regrowth (e.g., using a high resistance layer, a current blocking layer, a tunnel junction, or the like), or an air gap, among other examples.

The confinement aperture 112 may have a particular shape (e.g., when viewed from a top of the VCSEL 100), such as a circular shape, an elliptical shape, a polygonal shape, or the like. In some implementations, the confinement aperture 112 is asymmetrical with respect to at least one axis associated with the confinement aperture 112 (e.g., the confinement aperture 112 may not be rotationally symmetrical). For example, the confinement aperture 112 may have an elliptical shape (e.g., that is symmetrical about a major axis and a minor axis of the confinement aperture 112, but not another axis of the confinement aperture 112), or a rectangular shape (e.g., that is symmetrical about a length axis and a width axis of the confinement aperture 112, but not another axis of the confinement aperture 112), a teardrop shape (e.g. that is symmetrical about a length axis of the confinement aperture 112, but not another axis of the confinement aperture 112), among other examples. In this way, such as due to the particular shape of the confinement aperture 112 and the size of the confinement aperture 112, the confinement aperture 112 may be configured to reduce a quantity of optical modes supported by the confinement aperture 112 (and therefore supported by the VCSEL 100). For example, when the confinement aperture 112 is asymmetrical, one optical mode (e.g., a fundamental optical mode) can be enhanced and one or more other optical modes can be reduced and/or eliminated.

Accordingly, the confinement aperture 112 (e.g., due to the particular shape of the confinement aperture 112 and/or the size of the confinement aperture 112) may be configured to support a single optical mode. This may cause the VCSEL 100 to be a single-mode (SM) VCSEL (e.g., that emits a laser beam with only one optical mode, such as a fundamental optical mode). Alternatively, the confinement aperture 112 (e.g., due to the particular shape of the confinement aperture 112 and/or the size of the confinement aperture 112) may be configured to support one or more optical modes (e.g., by allowing lasing of the one or more optical modes and/or by suppressing lasing of one or more other optical modes). This may cause the VCSEL 100 to be a reduced-mode (RM) VCSEL (e.g., that emits a laser beam with a reduced number of optical modes, such as a fundamental optical mode and one or more higher order optical modes).

Top mirror structure 114 is a top reflector of the optical resonator of the VCSEL 100. For example, the top mirror structure 114 may include a DBR, a dielectric mirror, or the like. In some implementations, the top mirror structure 114 is formed from a p-type material. In some implementations, the top mirror structure 114 may have a thickness in a range from approximately 1 μm to approximately 6 μm, such as 3 μm. In some implementations, the top mirror structure 114 includes a set of layers (e.g., AlGaAs layers) grown using an MOCVD technique, an MBE technique, or another technique. In some implementations, the top mirror structure 114 is grown on or over the cavity region 108.

In some implementations, a total thickness from a bottom surface of the bottom mirror structure 106 to a top surface of the top mirror structure 114 may be in a range from, for example, approximately 4.5 μm to approximately 26.4 μm, such as approximately 8.6 μm. In some implementations, a thickness of one or more of the layers of the VCSEL 100 may be selected in order to provide a structure that achieves high reflectivity (e.g., greater than approximately 99% reflectivity). In some implementations, a smaller total thickness may facilitate growth time reduction of the VCSEL 100 or stress reduction within the VCSEL 100.

The top contact layer 116 makes electrical contact with the top mirror structure 114 through which current may flow. In some implementations, the top contact layer 116 includes an annealed metallization layer. For example, the top contact layer 116 may include a chromium-gold (Cr—Au) layer, a gold-zinc (Au—Zn), a titanium-platinum-gold (TiPtAu) layer, a gold-germanium-nickel (AuGeNi) layer, a palladium-germanium-gold (PdGeAu) layer, or the like. In some implementations, the top contact layer 116 has a thickness in a range from approximately 0.03 μm to approximately 0.3 μm, such as 0.2 μm. In some implementations, the top contact layer 116 has a ring shape, a slotted ring shape, a tooth wheel shape, or another type of circular or non-circular shape (e.g., depending on a design of the VCSEL 100).

Dielectric layer 118 is a layer that at least partially insulates the top metal 120 from one or more other layers or features (e.g., sidewalls of trenches). In some implementations, the dielectric layer 118 may include, for example, silicon nitride (SiN), silicon dioxide (SiO₂), a polymer dielectric, or another type of insulating material.

The top metal 120 is a top metal layer at a front side of the VCSEL 100. In some implementations, the top metal 120 is formed from a p-type material. Alternatively, in some implementations, the top metal 120 is formed from an n-type material. In some implementations, the top metal 120 may be a layer that makes electrical contact with the top contact layer 116. In some implementations, the top metal 120 may serve as a cathode for the VCSEL 100.

Isolation implant 122 is a region to prevent free carriers from reaching edges of trenches and/or to isolate adjacent VCSELs 100 from one another (e.g., when trenches do not fully enclose the VCSEL 100). Isolation implant 122 may include, for example, an ion implanted material, such as a hydrogen/proton implanted material or a similar implanted element to reduce conductivity.

Polarization mode filter 124 may be associated with polarization of light (e.g., a laser beam) emitted by the VCSEL 100. For example, the polarization mode filter 124 may introduce a polarization dependence to reflectivity and/or transmissivity of the VCSEL 100, an effect of which is suppression of one of the two orthogonal polarization orientations of the light (e.g., such that the light emitted by the VCSEL 100 has a single polarization orientation). Additionally, or alternatively, the polarization mode filter 124 may be associated with increasing reflectivity on a side of the VCSEL 100 that includes the top mirror structure 114.

Polarization mode filter 124 may be configured to lock a polarization of each optical mode of the one or more optical modes (e.g., of a laser beam) supported by the confinement aperture 112 (and therefore supported by the VCSEL 100). For example, when the confinement aperture 112 supports a single optical mode (e.g., when the VCSEL 100 is an SM VCSEL), the polarization mode filter 124 may cause the single optical mode to have a particular polarization and to not have any other polarization (e.g., by selecting the particular polarization of the single optical mode and/or filtering, or preventing selection of, another polarization). As another example, when the confinement aperture 112 supports one or more optical modes (e.g., when the VCSEL 100 is an RM VCSEL), the polarization mode filter 124 may cause each optical mode of the one or more optical modes to have a same polarization and to not have any other polarization (e.g., by selecting the same polarization for the one or more optical modes and/or filtering, or preventing selection of, one or more other polarizations).

In some implementations, the polarization mode filter 124 is on, under, or in at least one of the top mirror structure 114, the dielectric layer 118, or any other layer or structure above the confinement aperture 112. In some implementations, the polarization mode filter 124 may include a grating, which may have a grating depth and a grating period that are on an order of or lower than a wavelength of the VCSEL 100. In some implementations, the polarization mode filter 124 comprises an AlGaAs layer. In some implementations, a thickness of the polarization mode filter 124 may be in a range from approximately 0.06λ to approximately 0.26λ, where λ is a wavelength of the VCSEL 100. In one example, for a 940 nm wavelength (λ=940 nm), the thickness of the polarization mode filter 124 may be in a range from approximately 50 nm to approximately 250 nm.

In some implementations, when the polarization mode filter 124 includes a grating, the polarization mode filter may be oriented to a particular axis of the confinement aperture 112, such as a symmetrical axis of the confinement aperture 112. That is, a grating axis of the grating (e.g., a direction in which grooves of the grating extend) of the polarization mode filter 124 may be aligned with (e.g., is parallel to) the particular axis of the confinement aperture 112 (e.g., within a tolerance, such as 1, 2, or 3 degrees), or may be set at a particular angle (e.g., a non-zero angle) to the particular axis of the confinement aperture 112 (e.g., within the tolerance), such as 30 degrees, 45 degrees, 60 degrees, 75 degrees, or another angle. For example, when the confinement aperture 112 has an elliptical shape, the grating axis of the grating of the polarization mode filter 124 may be aligned with the major axis of the confinement aperture 112. As another example, when the confinement aperture 112 has a rectangular shape, the grating axis of the grating of the polarization mode filter 124 may be set at a particular angle (e.g., 20 degrees) to the length axis of the confinement aperture 112.

Output aperture 126 is an aperture of the VCSEL 100 through which light (e.g., a laser beam) is emitted. As shown, the output aperture 126 may be defined by one or more layers of the VCSEL 100, such as the top contact layer 116, the dielectric layer 118, the top metal 120, or the polarization mode filter 124. In some implementations, a size (e.g., a width in a given direction) of the output aperture 126 is in a range from approximately 1 μm to approximately 300 μm, such as 5 μm or 8 μm.

The number, arrangement, thicknesses, order, symmetry, or the like, of layers shown in FIG. 1 are provided as an example. In practice, the VCSEL 100 may include additional layers, fewer layers, different layers, differently constructed layers, or differently arranged layers than those shown in FIG. 1. For example, as noted above, the VCSEL 100 may in some implementations be a bottom-emitting VCSEL, and a structure similar to that shown in FIG. 1 may utilized for bottom emission, with appropriate modification to support bottom emission (e.g., an output aperture can be formed at a bottom of the VCSEL rather than a top of the VCSEL). Additionally, or alternatively, a set of layers (e.g., one or more layers) of the VCSEL 100 may perform one or more functions described as being performed by another set of layers of the VCSEL 100, and any layer may include more than one layer. While some implementations described herein are directed to a single VCSEL (e.g., VCSEL 100), some implementations include multiple VCSELs (e.g., multiple VCSELs 100).

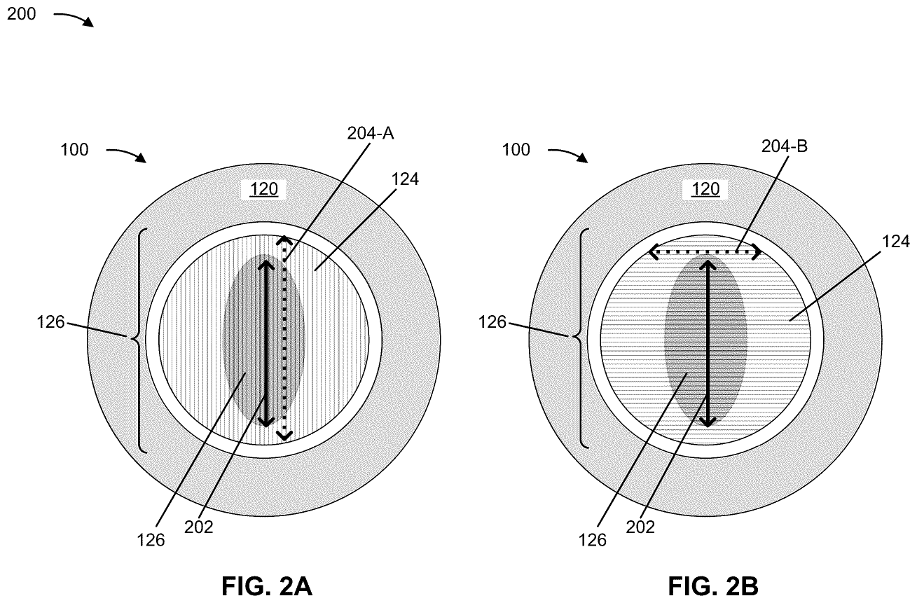

FIGS. 2A-2B are diagrams 200 depicting top-views of different configurations of the example VCSEL 100. As shown in FIGS. 2A-2B, the output aperture 126 may be surrounded (e.g., fully or partially surrounded) by the top metal 120. As further shown in FIGS. 2A-2B, the polarization mode filter 124 may be disposed above the confinement aperture 112 (e.g., as described above in relation to FIG. 1), which is shown as having an elliptical shape with a major axis 202 (e.g., that is a symmetrical axis of the confinement aperture 112).

FIG. 2A shows the polarization mode filter 124 including a grating that has a grating axis 204-A that is aligned with the major axis 202 of the confinement aperture 112 (e.g., the grating axis 204-A is parallel to the major axis 202). In this way, the grating of the polarization mode filter 124 is configured to reflect an optical mode (e.g., of a laser beam emitted by the VCSEL 100) with a polarization along the grating axis 204-A (and therefore along the major axis 202 of the confinement aperture 112). Further, the grating of the polarization mode filter 124 is configured to filter (or to prevent from reflecting) another optical mode (e.g., of a laser beam emitted by the VCSEL 100) with a polarization not along the grating axis 204-A (and therefore not along the major axis 202 of the confinement aperture 112), which therefore suppresses the other optical mode (e.g., by preventing a resonance required for laser action of the other optical mode). Accordingly, the grating of the polarization mode filter 124 locks polarization of any optical mode supported by the confinement aperture 112 along the grating axis 204-A (and therefore along the major axis 202 of the confinement aperture 112).

FIG. 2B shows the polarization mode filter 124 including a grating that has a grating axis 204-B that is set at an orthogonal angle (e.g., 90 degrees) to the major axis 202 of the confinement aperture 112 (e.g., the grating axis 204-B is orthogonal to the major axis 202). In this way, the grating of the polarization mode filter 124 is configured to reflect an optical mode (e.g., of a laser beam emitted by the VCSEL 100) with a polarization along the grating axis 204-B (and therefore orthogonal to the major axis 202 of the confinement aperture 112). Further, the grating of the polarization mode filter 124 is configured to filter (or to prevent from reflecting) another optical mode (e.g., of a laser beam emitted by the VCSEL 100) with a polarization not along the grating axis 204-B (and therefore not orthogonal to the major axis 202 of the confinement aperture 112), which therefore suppresses the other optical mode (e.g., by preventing a resonance required for laser action of the other optical mode). Accordingly, the grating of the polarization mode filter 124 locks polarization of any mode supported by the confinement aperture 112 along the grating axis 204-B (and therefore orthogonal to the major axis 202 of the confinement aperture 112).

As indicated above, FIGS. 2A-2B are provided as examples. Other examples may differ from what is described with regard to FIGS. 2A-2B.

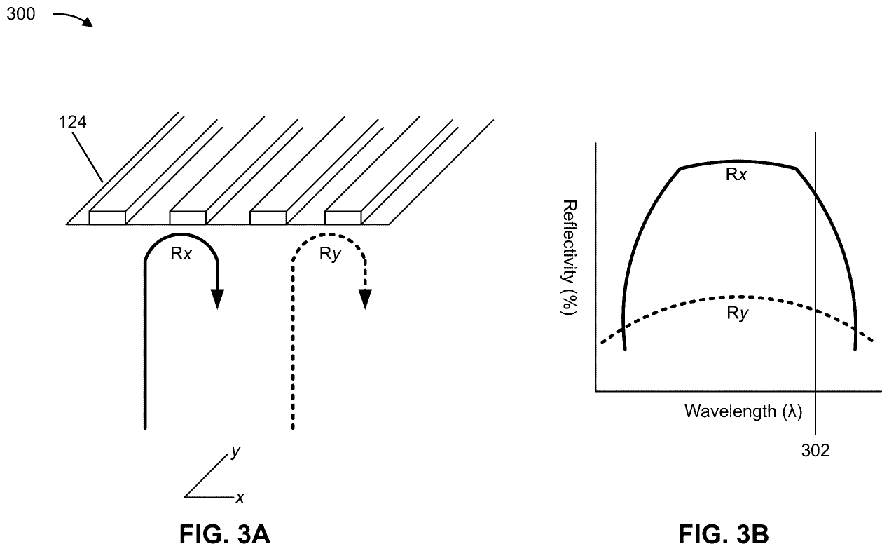

FIGS. 3A-3B are example diagrams 300 related to the polarization mode filter 124 of the VCSEL 100. FIG. 3A shows an example configuration of the polarization mode filter 124 that includes a grating, which has a grating axis that is aligned with (e.g., parallel to) the y axis (also shown in FIG. 3A). Accordingly, as further shown in FIG. 3A, the grating may include a plurality of grooves placed (e.g., according to a grating period) along the polarization mode filter 124 in a direction that is aligned with the x axis. As further shown in FIG. 3A, Rx is reflectivity, by the grating of the polarization mode filter 124, of light (e.g., an optical mode of a laser beam) with a polarization (e.g., a dominant electrical field) in a direction aligned with the x axis, and Ry is reflectivity, by the grating of the polarization mode filter 124, of light with a polarization in a direction aligned with the y axis.

As shown in FIG. 3B, Rx may be greater than Ry, such as for a wavelength 302 associated with a fundamental optical mode of the VCSEL 100. Accordingly, the grating of the polarization mode filter 124 may support resonance of light in the direction aligned with the x axis, and may suppress resonance of light in the direction aligned with the y axis. In this way, the grating of the polarization mode filter 124 may lock polarization of any optical mode supported by the confinement aperture 112 of the VCSEL 100 in the direction aligned with the x axis (e.g., along the grating axis of the polarization mode filter 124).

As indicated above, FIGS. 3A-3B are provided as examples. Other examples may differ from what is described with regard to FIGS. 3A-3B.

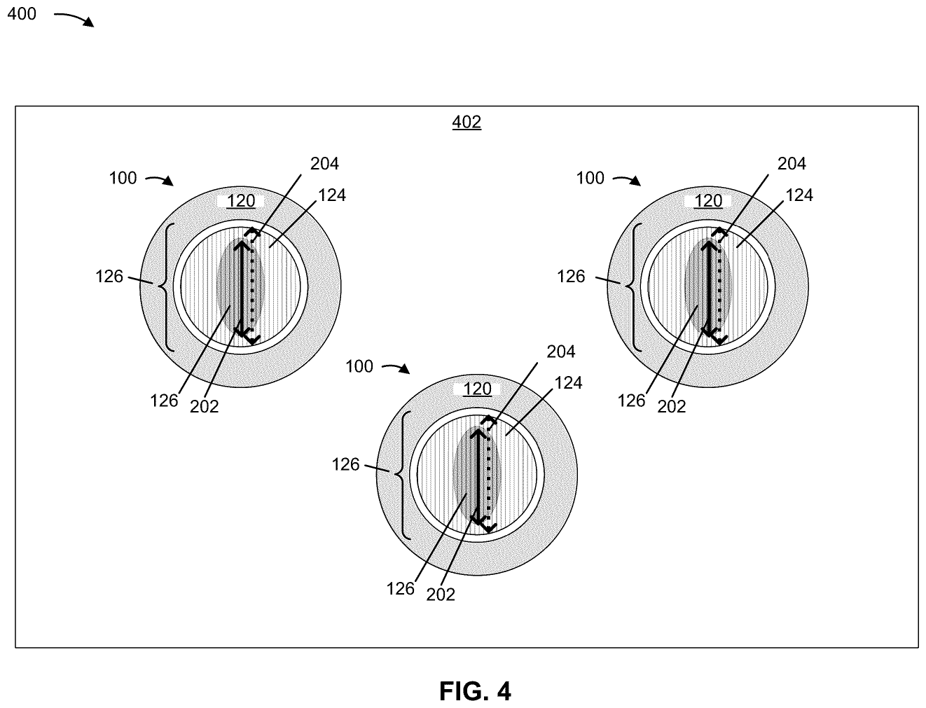

FIG. 4 is diagram associated with an example optical device 400. The example optical device 400 may be, for example, an optical communication device, an optical sensing device, an optical interconnection device, an optical structured light device, or another type of optical device. The optical device 400 may include an optical assembly 402, which may include one or more VCSELs 100 (shown in FIG. 3 as three VCSELs 100), which may be arranged in a pattern (e.g., a one dimensional array, a two-dimensional array, or another type of pattern) within the optical assembly 402.

The one or more VCSELs 100 may be configured to emit respective laser beams, such as respective laser beams that are to couple into (e.g., enter into) an input end of an optical fiber (e.g., a single mode or a multi-mode fiber). The respective laser beams may be associated with a same spectral range. That is, each VCSEL 100 may be configured to emit a laser beam associated with a particular spectral range. For example, each VCSELs 100 may be configured to emit a laser beam associated with a spectral range that has an 850 nm center wavelength.

Further, each VCSEL 100 may be configured to emit a laser beam that has one or more optical modes that are each locked to a particular polarization. For example, as shown in FIG. 4, each VCSEL 100 may include a confinement aperture 112 that supports one or more optical modes (e.g., to cause each VCSEL 100 to be an SM VCSEL or an RM VCSEL) and a polarization mode filter 124 that causes each optical mode of the one or more optical modes to have a same polarization (e.g., along a grating axis 204 of a grating of the polarization mode filter 124). Notably, the respective grating axes 204 of the one or more VCSELs 100 may be aligned with each other (e.g., parallel to each other, within a tolerance), which causes the one or more optical modes of each laser beam emitted by the one or more VCSELs to have the same polarization. This may facilitate coupling of the laser beams into the optical fiber (e.g., by ensuring that the polarization of the laser beams is aligned with a polarization axis of the optical fiber).

As indicated above, FIG. 4 is provided as an example. Other examples may differ from what is described with regard to FIG. 4.

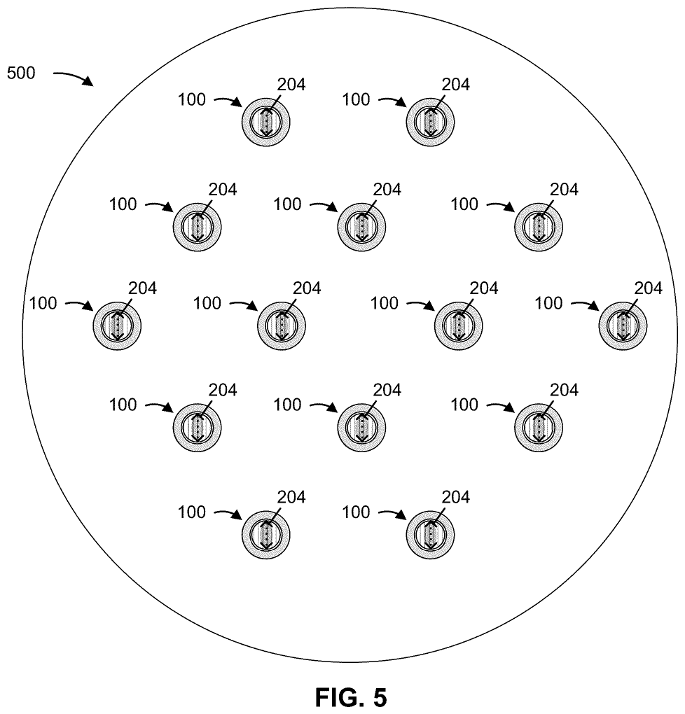

FIG. 5 is diagram associated with an example wafer 500. The wafer 500 may be used to produce integrated circuits, chips, semiconductor lasers, and/or the like. For example, the wafer 500 may be used to form a plurality of VCSELs 100 (e.g., where the plurality of VCSELs 100 are formed on a uniform substrate and then a singulation process can be used to individualize the VCSELs 100 using).

As shown in FIG. 5, the plurality of VCSELs 100 may be formed on a surface (e.g., a top surface) of the wafer 500. As described elsewhere herein, each VCSEL 100 may be configured to support one or more optical modes (e.g., due to a confinement aperture 112 of the VCSEL 100), wherein each optical mode has a locked polarization (e.g., due to a polarization mode filter 124 of the VCSEL 100), such as in a same direction. For example, as shown in FIG. 5, each VCSEL 100 may be configured to emit a laser beam that includes one or more optical modes (e.g., the VCSEL 100 is an SM VCSEL or an RM VCSEL due to the confinement aperture 112 of the VCSEL 100). Each optical mode may have a same polarization (e.g., along a grating axis 204 of a grating of the polarization mode filter 124 of the VCSEL 100). Notably, as shown in FIG. 5, the respective grating axes 204 of the polarization mode filters 124 of the plurality of VCSELs 100 may be aligned with each other (e.g., parallel to each other, within a tolerance), which causes the VCSELs 100 to be configured to emit respective laser beams that each have one or more optical modes with the same polarization.

As indicated above, FIG. 5 is provided as an example. Other examples may differ from what is described with regard to FIG. 5.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A vertical-cavity surface-emitting laser (VCSEL), comprising:
a confinement layer; and
a polarization mode filter, wherein:
the confinement layer defines a confinement aperture,
the confinement aperture is asymmetrical with respect to at least one axis of the confinement aperture, and
the polarization mode filter includes a grating, and
the confinement aperture and the polarization mode filter are configured to control a quantity of optical modes supported by the VCSEL and to lock a polarization of each optical mode supported by the VCSEL.

2. The VCSEL of claim 1, wherein:
the confinement aperture is configured to reduce the quantity of optical modes supported by the VCSEL.

3. The VCSEL of claim 1, wherein:
a grating axis of the grating of the polarization mode filter is aligned with a symmetrical axis of the confinement aperture.

4. The VCSEL of claim 3, wherein:
the polarization mode filter is configured to lock a polarization of each optical mode supported by the VCSEL along the grating axis of the grating of the polarization mode filter and the symmetrical axis of the confinement aperture.

5. The VCSEL of claim 1, wherein:
a grating axis of the grating of the polarization mode filter is set at a non-zero angle to a symmetrical axis of the confinement aperture.

6. The VCSEL of claim 5, wherein:
the polarization mode filter is configured to lock a polarization of each optical mode supported by the VCSEL along the grating axis of the polarization mode filter and not along the symmetrical axis of the confinement aperture.

7. The VCSEL of claim 1, wherein:
the confinement layer is above a cavity region of the VCSEL, which is above a substrate of the VCSEL; and
the polarization mode filter is above the confinement aperture.

8. An optical assembly, comprising:
one or more vertical cavity surface emitting lasers (VCSELs), wherein each VCSEL comprises:
a confinement layer; and
a polarization mode filter, wherein:
the confinement layer defines a confinement aperture, and
the confinement aperture and the polarization mode filter are configured to control a quantity of optical modes supported by the VCSEL and to lock a polarization of each optical mode supported by the VCSEL.

9. The optical assembly of claim 8, wherein:
the confinement aperture is asymmetrical with respect to at least one axis of the confinement aperture.

10. The optical assembly of claim 8, wherein:
the polarization mode filter includes a grating.

11. The optical assembly of claim 8, wherein:
the polarization mode filter is configured to lock a polarization of each optical mode supported by the VCSEL along a grating axis of a grating of the polarization mode filter.

12. The optical assembly of claim 11, wherein:
the grating axis of the grating of the polarization mode filter is aligned with a symmetrical axis of the confinement aperture.

13. The optical assembly of claim 11, wherein:
the grating axis of the grating of the polarization mode filter is set at a non-zero angle to a symmetrical axis of the confinement aperture.

14. The optical assembly of claim 11, wherein:
the confinement layer is above a cavity region of the VCSEL, which is above a substrate of the VCSEL; and
the polarization mode filter is above the confinement aperture.

15. A wafer, comprising:
a plurality of vertical cavity surfacing emitting lasers (VCSELs), wherein each VCSEL comprises:
a confinement layer that defines a confinement aperture; and
a polarization mode filter, wherein:
the confinement aperture and the polarization mode filter are configured to control a quantity of optical modes supported by the VCSEL and to lock a polarization of each optical mode supported by the VCSEL.

16. The wafer of claim 15, wherein:
the confinement aperture is asymmetrical with respect to at least one axis of the confinement aperture.

17. The wafer of claim 15, wherein:
the polarization mode filter includes a grating.

18. The wafer of claim 17, wherein:
the polarization mode filter is configured to lock a polarization of each optical mode supported by the VCSEL along a grating axis of the grating of the polarization mode filter.

19. The wafer of claim 17, wherein:
grating axes of the gratings of the polarization mode filters of the plurality of VCSELs are aligned with each other.

20. The wafer of claim 15, wherein:
the plurality of VCSELs are configured to emit respective laser beams that each have one or more optical modes with a same polarization.
